(19) United States
(12) Patent Application Publication
(10) Pub. No.: US 2026/0255896 A1
(43) Pub. Date: Aug. 27, 2026

(54) SEMICONDUCTOR WAFER AND DEVICE INCLUDING IMPURITY ADSORPTION LAYER

(71) Applicant: SK keyfoundry Inc., Cheongju-si (KR)

(72) Inventors: Hanseob CHA, Sejong-si (KR); Yongjun CHOI, Seoul (KR); Bomin KIM, Jinju-si (KR)

(73) Assignee: SK keyfoundry Inc., Cheongju-si (KR)

(21) Appl. No.: 19/456,326

(22) Filed: Jan. 22, 2026

(30) Foreign Application Priority Data
Feb. 21, 2025 (KR) 10-2025-0022758

(51) Int. Cl. H10P 30/28; H10D 84/01; H10P 14/20; H10P 90/00

(52) U.S. Cl. CPC H10P 30/28; H10D 84/0151; H10D 84/0156; H10P 14/3411; H10P 14/3456; H10P 90/123

(57) ABSTRACT

A semiconductor device includes a substrate having a first surface and a second surface opposite the first surface, and an impurity adsorption layer including polycrystalline silicon disposed on the second surface. An epitaxial layer is disposed on the first surface of the substrate. The impurity adsorption layer is configured to getter impurities from within the substrate and the epitaxial layer, thereby preventing the accumulation of impurities at crystalline defects near the first surface. By preferentially trapping impurities during high-temperature thermal processes, the impurity adsorption layer suppresses the formation of unwanted compounds that cause cone defects during subsequent etching processes, such as shallow trench isolation (STI) formation.

### CROSS-REFERENCE TO RELATED APPLICATION

This application claims the benefit under 35 U.S.C. §119(a) of Korean Patent Application No. 10-2025-0022758, filed on February 21, 2025, the entire disclosure of which is incorporated herein by reference for all purposes.

### BACKGROUND

### 1. Field

The following description relates to a semiconductor wafer that may be stably produced without defects by including an impurity adsorption layer, and a device including the same.

### 2. Discussion of Related Art

The statements in this section merely provide background information related to the present disclosure and do not necessarily constitute prior art.

During the semiconductor manufacturing process, wafer surface defects can arise from various sources. Specifically, in products featuring an epitaxial layer, if foreign substances or defects exist on the substrate just before the process of growing the epitaxial layer, defects might occur in the epitaxial layer, and even for products that do not include an epitaxial layer, lattice defects may occur during the implant process in areas with high doping concentration.

Defects formed on the wafer surface due to these various reasons can cause contaminants surrounding the defects to getter and form various compounds when a thermal process is performed. These compounds act as etch barriers during the subsequent shallow trench isolation (STI) process. When the wafer is etched to form trenches, these barriers cause cone-shaped or frustum-shaped defects (hereinafter referred to as “cone defects”) to form beneath the compounds. These cone defects not only reduce product yield but also cause serious quality issues.

These defects are especially likely to form when the temperature of the dopant drive-in process is high. Therefore, they are particularly problematic in the BCD (Bipolar-CMOS-DMOS) process, where a high-temperature dopant drive-in process is essential to achieve high voltage.

This is particularly problematic in the BCD (Bipolar-CMOS-DMOS) process, where a high-temperature dopant drive-in process is essential to achieve high voltage. The BCD process is a process used to manufacture power management integrated circuit products, and is one of the non-memory semiconductor manufacturing processes that has been in the spotlight for the past decade.

Most foundries are unable to resolve the yield and quality issues caused by these cone defects, and instead of directly solving the cone defect problem, they add a LOCOS process after STI at an additional high process cost as a means of avoiding it, and manufacturing the core BCD device by LOCOS rather than STI.

The present disclosure proposes a formation mechanism for these cone defects and relates to a method of fundamentally removing the cone defects based on that mechanism.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Accordingly, one object of the present disclosure is to solve the above-noted disadvantages of the prior art, and to provide a semiconductor wafer that may fundamentally suppress the formation of cold defects and a device structure including the same.

The objects of the present disclosure are not limited to those mentioned above, and other technical objects may be inferred from following embodiments.

In one general aspect, a semiconductor device includes a substrate having a first surface and a second surface opposite the first surface; and an impurity adsorption layer including polycrystalline silicon disposed on the second surface of the substrate, the impurity adsorption layer configured to trap impurities introduced during a fabrication process of the semiconductor device.

The substrate may include silicon, silicon carbide, or sapphire, and the substrate may be doped with a P-type or an N-type dopant.

The impurity adsorption layer may be further disposed on a lateral surface of the substrate.

The impurity adsorption layer may have a thickness in a range of 0.05 μm to 5 μm.

In another general aspect, a method of manufacturing a semiconductor device includes forming a semiconductor ingot; grinding a surface of the semiconductor ingot to form a substrate in a shape of a wafer, cleaning the substrate to remove foreign substances and inspecting the substrate for remaining foreign substances; performing a heat treatment on the substrate to remove impurities from within the substrate and to flatten a first surface of the substrate; depositing an impurity adsorption layer on a second surface of the substrate, the second surface being opposite the first surface; polishing the first surface of the substrate; and grinding an edge portion of the substrate and a lateral surface of the impurity adsorption layer.

The depositing of the impurity adsorption layer may include depositing polycrystalline silicon on the second surface of the substrate via a LPCVD (Low-Pressure Chemical Vapor Deposition) process or a PECVD (Plasma-Enhanced Chemical Vapor Deposition) process.

The depositing of the impurity adsorption layer on the second surface of the substrate may include cleaning the second surface of the substrate to remove impurities; depositing a silicon oxide film on the first surface of the substrate using TEOS (Tetra Ethyl Ortho Silicate, Si(OC2H5)4) as a precursor; cleaning the silicon oxide film and the second surface of the substrate; depositing a polycrystalline silicon layer on the first, second, and lateral surfaces of the substrate, such that the

polycrystalline silicon layer may cover the silicon oxide film; removing a portion of the polycrystalline silicon layer covering the silicon oxide film; and removing the silicon oxide film from the first surface of the substrate.

The depositing of the silicon oxide film on the first surface of the substrate may include depositing the silicon oxide film to a thickness in a range of 2nm to 500nm.

The depositing of the polycrystalline silicon layer on the first, second, and lateral surfaces of the substrate and the silicon oxide film may include depositing the polycrystalline silicon layer to a thickness in a range of 50 nm to 5000 nm.

In another general aspect, a semiconductor device includes a substrate including silicon, silicon carbide, or sapphire, the substrate being doped with a P-type dopant and having a first surface and a second surface opposite the first surface; an impurity adsorption layer including polycrystalline silicon disposed on the second surface of the substrate; an N-type buried layer disposed on the first surface of the substrate; an epitaxial layer disposed on the N-type buried layer; a high voltage N-type deep well region and a P-type deep well region disposed in the epitaxial layer; a device isolation film including an insulating material disposed on an upper portion of the epitaxial layer; a P-type well region disposed in the epitaxial layer or the P-type deep well region; an N-type well region disposed in the high voltage N-type deep well region; and a drain electrode, a source electrode, and a gate electrode disposed on the epitaxial layer.

The semiconductor device may further include an N-type sink region disposed within the high voltage N-type deep well region; and a deep trench including an insulating material, the deep trench extending from an upper portion of the epitaxial layer, through the N-type buried layer, and into the substrate.

In another general aspect, a method of manufacturing a semiconductor device may include: providing a substrate including silicon, silicon carbide or sapphire, the substrate being doped with a P-type dopant and having a first surface and a second surface opposite the first surface; forming an impurity adsorption layer by depositing polycrystalline silicon on the second surface of the substrate; forming an N-type buried layer on the first surface of the substrate; forming an epitaxial layer on the N-type buried layer; forming a high voltage N-type deep well region and a P-type deep well

region in the epitaxial layer; forming a device isolation film including an insulating material on an upper portion of the epitaxial layer; forming a P-type well region within at least one of the epitaxial layer and the P-type deep well region; forming an N-type well region within the high voltage N-type deep well region; forming a gate electrode on the epitaxial layer; and forming an N+ region and a P+ region within the N-type well region and the P-type well region, respectively, to define source and drain regions.

The forming of the N-type buried layer on the first surface of the substrate includes: doping the first surface of the substrate with antimony (Sb) at a concentration of 1.0E14/cm² to 1.0E17/cm²; and performing a heat treatment process at a temperature in a range of 900 to 1,300 degrees Celsius to diffuse the antimony and form the N-type buried layer.

The method may further include forming a plurality of N-type sink regions within the high voltage N-type deep well region prior to forming the device isolation film; and performing a heat treatment process at a temperature in a range of 900 to 1,300 degrees Celsius to drive in the N-type sink region.

The method may further include forming a deep trench including an insulating material, the deep trench extending from an upper surface of the epitaxial layer, through the N-type buried layer, and into the substrate, after forming the gate electrode.

The method may further include performing a heat treatment process at a temperature in a range of 900 to 1,300 degrees Celsius during the forming the P-type deep well region and the high voltage N-type deep well region.

The forming of the device isolation film on the upper portion of the epitaxial layer may further include performing a heat treatment process at a temperature in a range of 900 to 1,300 degrees Celsius.

The method may further include performing a heat treatment process at a temperature in a range of 900 to 1,300 degree Celsius during the forming the deep trench.

The method may further include forming an N-type drift region and a P-type body region within an upper portion of the P-type deep well region, subsequent to forming the high voltage N-type deep well region and the P-type deep well region.

The forming of the N+ region and the P+ region may include forming an N+ region within the N-type drift region, and forming an N+ source region and a P+ region within the P-type body region.

According to the embodiment of the present disclosure, the formation of cone defects may be effectively prevented and device performance may be improved by adding the impurity adsorption layer to the semiconductor wafer and device and improve device performance.

Further scope of applicability of the present invention will become apparent from the detailed description given hereinafter. However, it should be understood that the detailed description and specific examples, while indicating preferred embodiments of the invention, are given by illustration only, since various changes and modifications within the spirit and scope of the invention will become apparent to those skilled in the art from this detailed description.

Other features and aspects will be apparent from the following detailed description, the drawings, and the claims.

### BRIEF DESCRIPTION OF THE DRAWINGS

FIG. 1 illustrates the structure of a semiconductor wafer including an impurity adsorption layer according to an embodiment;

FIGS. 2 to 4 illustrate a process of forming cone defects;

FIG. 5 illustrates a process in which an impurity adsorption layer removes contaminants on the wafer surface;

FIG. 6 illustrates the difference in the degree of cone defect formation based on the presence or absence of the impurity adsorption layer according to an embodiment;

FIG. 7 illustrates a manufacturing process of a semiconductor wafer including an impurity adsorption layer;

FIGS. 8 to 11 illustrate a process of depositing the impurity adsorption layer according to an embodiment;

FIG. 12 illustrates a manufacturing process of a BCD semiconductor device including an impurity adsorption layer; and

FIGS. 13 to 16 illustrate a manufacturing method of a BCD semiconductor device including an impurity adsorption layer according to an embodiment.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

Description will now be given in detail according to exemplary embodiments disclosed herein, with reference to the accompanying drawings. For the sake of brief description with reference to the drawings, the same or equivalent components may be provided with the same reference numbers, and description thereof will not be repeated.

Description will now be given in detail according to exemplary embodiments disclosed herein, with reference to the accompanying drawings. Throughout the disclosure, it will be understood that when an element (e.g., region, layer, portion, etc.) is referred to as being “connected with”, “on” or “coupled to” another element, the element can be directly connected with the other element or intervening elements may also be present. In contrast, when an element is referred to as being “directly connected with” another element, there are no intervening elements present.

Terms such as “comprise” or “comprising” are used herein and should be understood that they are intended to indicate an existence of several components, functions or steps, disclosed in the specification, and it is also understood that greater or fewer components, functions, or steps may likewise be utilized.

The use of the term "may" herein with respect to an example or embodiment, e.g., as to what an example or embodiment may include or implement, means that at least one example or embodiment exists where such a feature is included or implemented, while all examples are not limited thereto.

It will be understood that although the terms first, second, etc. may be used herein to describe various elements, these elements should not be limited by these terms.

These terms are generally only used to distinguish one element from another. It will be understood that the terms “first” and “second” are used herein to describe various components but these components should not be limited by these terms. The above terms are used only to distinguish one component from another. For example, a first component may be referred to as a second component and vice versa without departing from the scope of the invention. The singular expressions include plural expressions unless the context clearly dictates otherwise.

The terms ‘part’ or ‘module’ used in embodiments may mean a software or hardware element such as an FPGA or ASIC, and the ‘part’ or ‘module’ may perform predetermined roles. However, ‘part’ or ‘module’ is not limited to the software or hardware. The “part” or “module” may be provided in an addressable storage medium and configured to cause one or more processors to execute. Accordingly, as one example, a “part” or “module” may include elements such as software elements, object-oriented software elements, class elements and task elements, as well as processes, functions, attributes, procedures, subroutines, segments of program code, drivers, firmware, microcode, circuitry, data, database, data structures, tables, arrays and variables. The functions provided within the elements and “parts” or “modules” may be combined and “sub-part” or “modules” or further separated into additional elements and “parts” or “modules.

The steps of a method or algorithm described in connection with some embodiments of the present disclosure may be directly implemented in hardware, in a software module executed by a processor, or in a combination of the two. The software module may be provided in RAM memory, flash memory, ROM memory, EPROM memory, EEPROM memory, registers, a hard disk, a removable disk, a CD-ROM, or any other form of storage medium known in the art. An exemplary storage medium may be coupled to a processor such that the processor may read information from the storage medium and write information to the storage medium. Alternatively, a recording medium may be integral with the processor. The processor and the recording medium may be provided in an application specific integrated circuit ASIC. The ASIC may be provided in a user terminal.

Hereinafter, referring to the accompanying drawings, embodiments of the present disclosure will be described in detail, to be understood by those skilled in the art to which the present disclosure pertains. However, the present disclosure may be embodied in various modified examples, and is not limited to embodiments described herein.

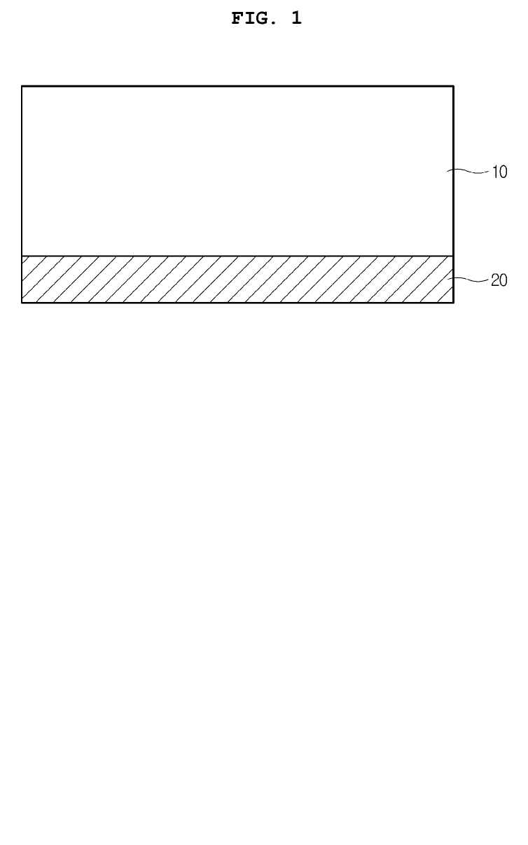

FIG. 1 illustrates a structure of a semiconductor wafer including an impurity adsorption layer according to an embodiment.

Referring to FIG. 1, an impurity adsorption layer 20 may be formed on a lower portion (e.g., a back surface) of a substrate 10. The substrate 10 may be formed of a single crystal material such as silicon (Si), silicon carbide (SiC), or sapphire. At this time, the substrate 10 may be doped with a P-type dopant such as boron (B). In addition, an N-type dopant may be used to form an N-type substrate. In cases where the substrate 10 is formed of sapphire, since sapphire has high strength and insulating properties, doping may be difficult. Therefore, a semiconductor material layer such as gallium nitride (GaN) may be additionally deposited on the substrate 10, and P-type doping may be performed on the semiconductor material layer.

The impurity adsorption layer 20 may be formed of polycrystalline silicon (Poly Si). The thickness of the impurity adsorption layer 20 may be varied to a level where a gettering effect is achieved, and may be set within a range of 0.05 μm to 5 μm. Since the impurity adsorption layer 20 is formed on the lower portion of the substrate 10,

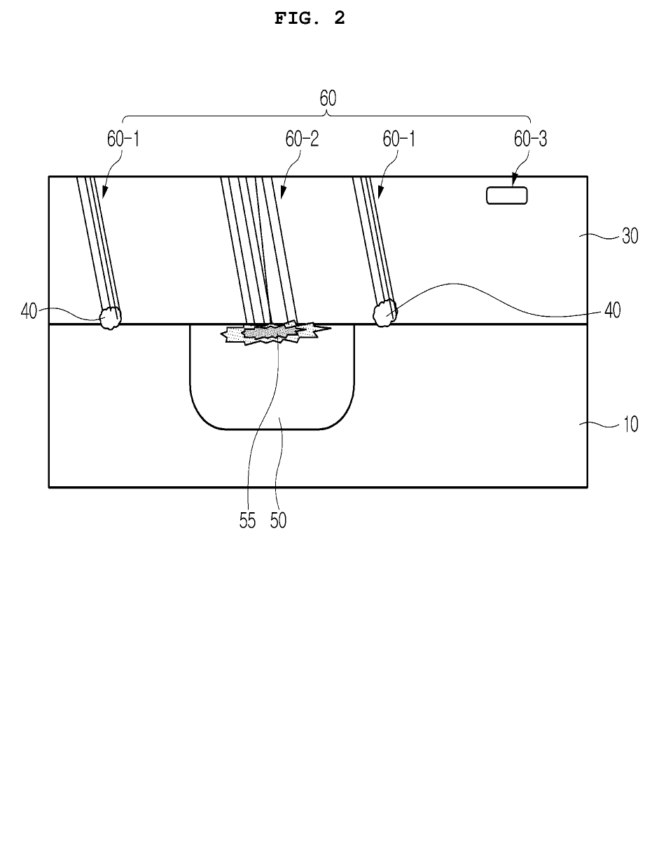

when a high-temperature thermal process is performed, contaminants on the upper portion of the substrate 10 are gettered by the impurity adsorption layer 20, thereby suppressing the formation of cone defects on the substrate 10. The mechanism of forming the cone defects and the mechanism by which the impurity adsorption layer 20 suppresses the formation of the cone defects are described in detail later with reference to FIGS. 2 to 5.

FIGS. 2 to 4 illustrate a process of forming cone defects;

Referring to FIG. 2, an epitaxial layer 30 may be grown and formed on the substrate 10 for the purpose of manufacturing a semiconductor device. The epitaxial layer 30 may be formed of various crystalline materials such as silicon (Si), gallium nitride (GaN), silicon carbide (SiC), and gallium arsenide (GaAs). According to one embodiment, the epitaxial layer may be doped with a P-type or an N-type.

Referring to FIG. 2, if a fine contaminant 40 remains on the substrate 10 prior to growing the epitaxial layer 30, a defect 60 may be formed within the epitaxial layer 30 during the epitaxial growth process. The formation of the defect 60 may be attributed to the lattice constant of the contaminant 40 failing to match that of the substrate 10 or the epitaxial layer 30, thereby generating stress which hinders the growth of the epitaxial layer 30. Additionally, the defect may be caused by a chemical reaction induced by the contaminant 40, or a temperature gradient that might occur across the substrate 10 due to the contaminant 40. A defect that occurs in the epitaxial layer 30 due to the contaminant 40 remaining on the substrate 10 is referred to herein as a first defect 60-1.

Referring again to FIG. 2, in a power semiconductor device or an integrated circuit, an N-type buried layer (NBL) 50 may be formed on the substrate 10 before growing the epitaxial layer 30 to facilitate current flow and ensure efficient operation of the power device. The N-type buried layer 50 may be formed by introducing an N-type dopant such as arsenic (As), phosphorus (P), or antimony (Sb) into a P-type doped substrate 10 through a diffusion or ion implantation process and then performing an annealing process. During the introduction of the N-type dopant and the subsequent annealing process, various types of micro-damage 55 may occur on the substrate 10. Due to such micro-damage 55, a defect 60-2 may be formed in the epitaxial layer 30 during the growth process of the epitaxial layer 30, similar to the formation of the first defect. A defect 60-2 created during the formation process of the N-type buried layer 50 is referred to herein as a second defect 60-2.

Referring to FIG. 2, subsequent to growing the epitaxial layer 30, a dopant may be introduced into the epitaxial layer 30 through a diffusion or ion implantation process, followed by a heat treatment process, to form a high concentration implant region for thermal management of the power device and to facilitate current flow. During this process, micro-damage may occur in a manner similar to that described for the formation of the second defect 60-2. Such micro-damage may be directly induced within the epitaxial layer 30 to form a defect 60-3. The defect formed in this way may be referred to as a third defect 60-3. As will be described in further detail below, when the heat treatment process is performed, impurities surrounding the defects 60 may be gettered to form an undesirable compound material.

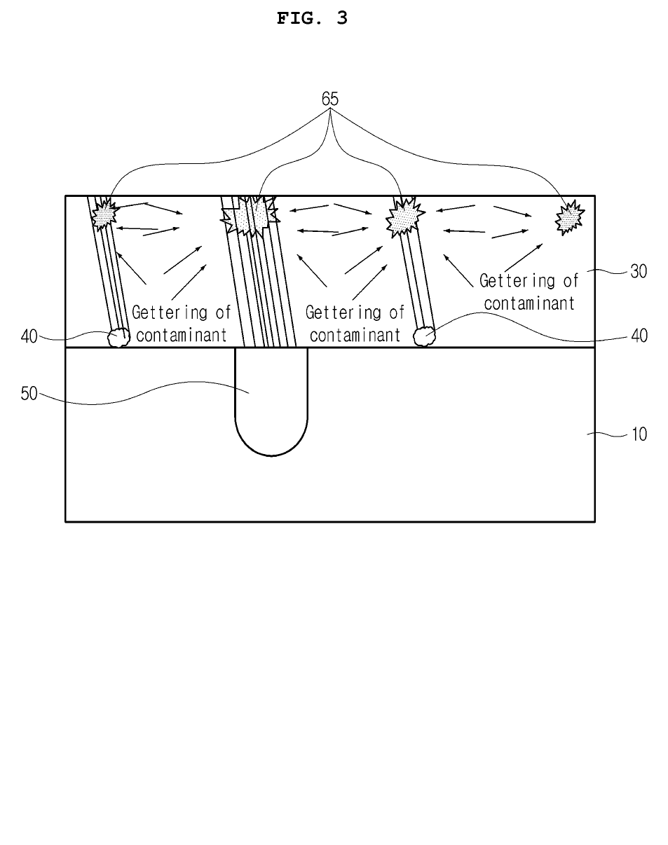

Specifically, as shown in FIG. 3, when a high-temperature thermal process is performed while the defect 60 described above exists, contaminants precipitate around the defect site, forming an unwanted compound 65.

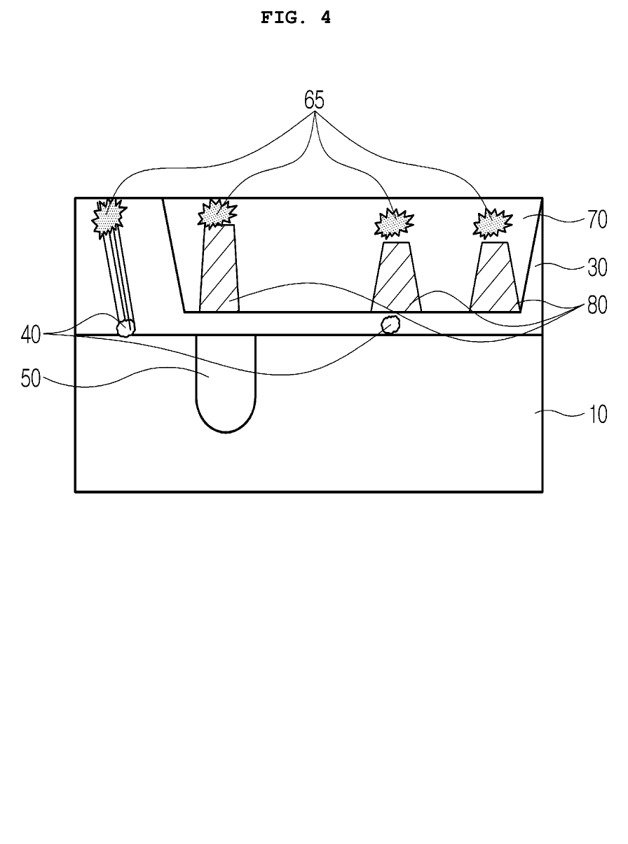

Referring to FIG. 4, when an STI (shallow trench isolation) process is performed on the epitaxial layer 30 in which an unwanted compound 65 has formed, the unwanted compound 65 may act as an etch barrier that interferes with etching and trench formation, thereby forming a cone defect 80. In FIG. 4, a region 70 where the STI process is performed is shown as being separated from a region where the process is not performed. The cone defect 80 interferes with etching during the STI process due to the unwanted compound 65, which creates a difference in crystal structure from other regions where the unwanted compound 65 is not generated, and during the heat treatment process, impurities within the epitaxial layer 30 accumulate around the defect 60, resulting in the growth of a compound that can extend to the upper portion of the epitaxial layer 30. This phenomenon occurs because the region where the defect 60 is formed possesses a different crystal structure compared to other regions of the epitaxial layer 30. Such cone defects 80 can cause a decrease in the performance and yield of the device.

The contaminant 40 causing the first defect can be reduced through a separate wafer cleaning process, and the second defect can be reduced through a cleaning process after forming the N-type buried layer 50, but there is a problem of high process difficulty in reducing the microdamage that occurs while forming a high-concentration implant area during the process.

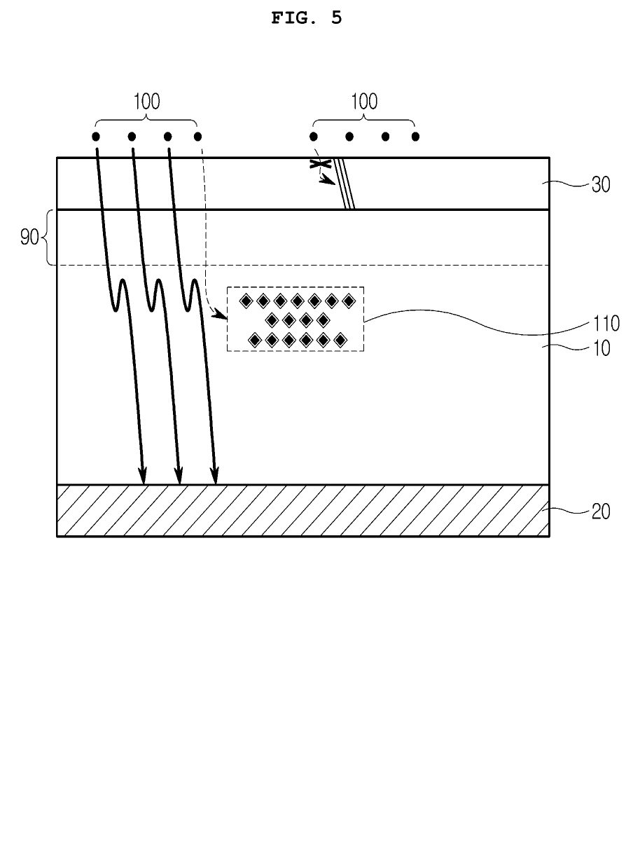

FIG. 5 illustrates a process in which an impurity adsorption layer removes contaminants on the wafer surface.

Referring to FIG. 5, the impurities accumulated within the first to third defects primarily comprise substances remaining from ion implantation equipment used on the epitaxial layer 30 or the substrate 10, residual photoresist that is not completely removed during processing, or impurities introduced from high-temperature diffusion furnaces. During standard semiconductor processing, oxygen precipitates (Bulk Micro Defects: BMDs) 110 are formed inside a silicon wafer, and certain impurities inside the wafer are removed via the gettering effect of the BMDs. However, the degree of impurity removal provided by the BMDs is insufficient to remove all remaining impurities. In addition, the effectiveness of the gettering may vary depending on the density of the BMD generation and the thermal budget of the fabrication process.

Ultimately, impurity removal through the BMD is not sufficient, and a large amount of impurities 100 may be adsorbed on the first to third defects to form cone defects 80. At this time, when an impurity adsorption layer 20 formed of polycrystalline silicon is deposited on the lower portion of the substrate 10, the gettering ability becomes much more excellent compared to BMD due to the characteristics of polycrystalline silicon having many defect structures between crystals compared to the first to third defects. The degree to which the impurity 100 is adsorbed into the impurity adsorption layer 20 is much stronger, so that the impurity 100 is gathered into the impurity adsorption layer 20 rather than into the first to third defects, and as a result, the formation of the cone defects 80 can be suppressed at a high level, and the performance and reliability of the device can be stably maintained.

That is, impurities 100 are prevented from accumulating within the epitaxial layer 30, and are instead gettered by the impurity adsorption layer 20 disposed on the back surface of the substrate 10. Accordingly, cone defects 80 are not formed in the

epitaxial layer 30, which is a region where a device is formed. According to one embodiment, when the subsequent heat treatment process is performed at a temperature in a range of 900 and 1,300 degrees Celsius, the gettering effect of the impurity adsorption layer 20 is maximized, thereby suppressing the formation of cone defects 80 to a high level. The denuded zone 90 corresponds to a region near the surface of the substrate 10 that is substantially free of oxygen precipitates and crystal defects in a silicon wafer process, and in which the BMD is not formed.

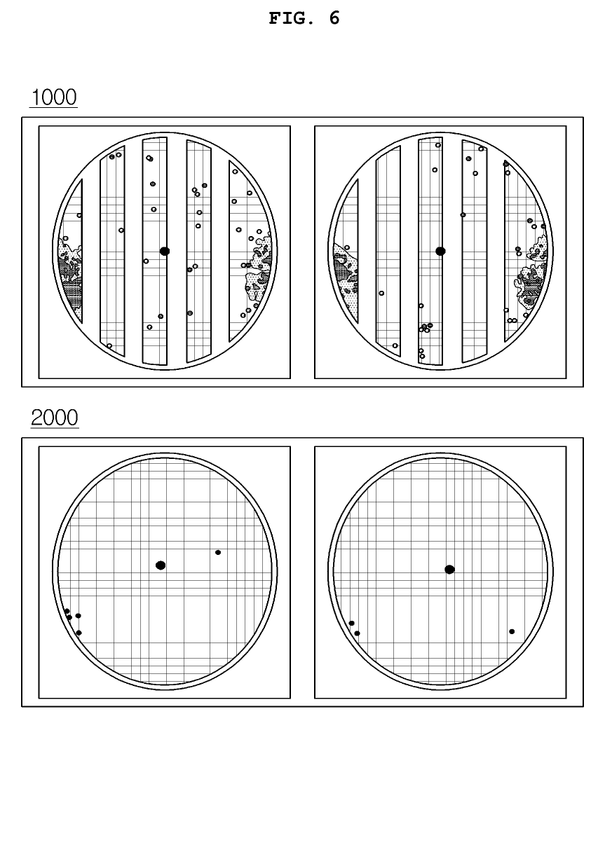

FIG. 6 illustrates the difference in the degree of cone defect formation based on the presence or absence of the impurity adsorption layer according to an embodiment.

Referring to FIG. 6, comparative experimental result 1 (1000) showing an area where a cone defect is formed on the surface of the substrate 10 that does not include the impurity adsorption layer 20 and experimental result 2 (2000) showing an area where a cone defect is formed on the surface of the substrate 10 on which the impurity adsorption layer 20 is deposited thereunder are illustrated. According to one embodiment, in comparative experimental result 1 (1000), it can be seen that 105,940 and 63,565 the cone defects 80 are formed on a single wafer, respectively, which may significantly deteriorate the performance of a semiconductor device. In contrast, in the experimental results 2 (2000), 5 and 3 cone defects 80 were formed on a single wafer, respectively, so that almost no cone defects 80 were formed, and thus the performance of the semiconductor device can be excellent.

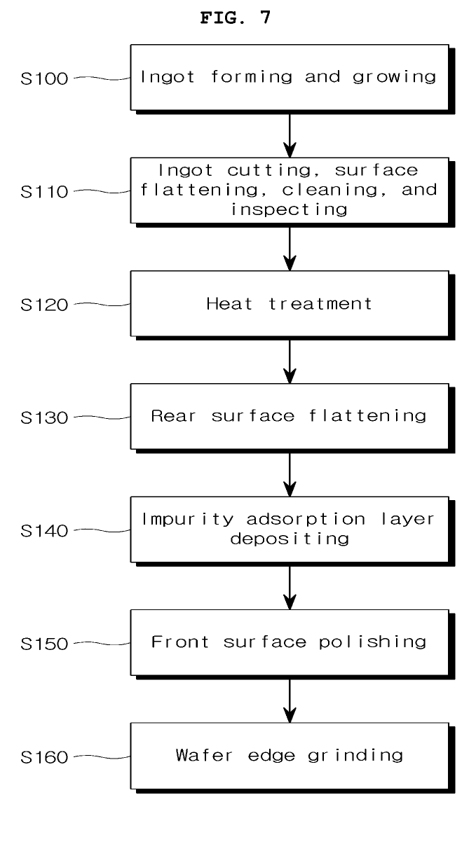

FIG. 7 illustrates a manufacturing process of a semiconductor wafer including an impurity adsorption layer.

Referring to FIG. 7, in the ingot formation and growth step S100, various methods may be employed depending on the material of the substrate. In the case of a silicon substrate, metallurgical-grade silicon is purified and a high-purity ingot is grown through a CZ (Czochralski) process or a FZ (Float-zone) process. In the case of a sapphire substrate, which possesses high heat resistance and mechanical strength, a high-purity ingot can be grown by continuously rotating a sapphire melt using a helical growth method. For silicon carbide (SiC) substrates, high-purity ingots

can be grown by growing silicon carbide in a high-temperature gas using PVT (Physical Vapor Transport).

In the ingot cutting, surface grinding, cleaning and inspection step S110, after the ingot growth is completed, a trailing process is performed to remove impurities at the end of the ingot and improve the crystal structure, so that the end of the ingot can be physically separated or heat treated to a certain extent. In addition, the end of the ingot can be further de-faulted through the ingot cropping process. Afterwards, the surface of the ingot can be made uniform through the grinding process, and the end of the ingot can be made flat through the flattening process. Afterwards, the ingot can be cut into a thin wafer shape and the edges of the wafer surface can be ground round. The wafer serves as a substrate 10. Afterwards, a wafer lapping process may be performed to remove unevenness and defects on the surface of the wafer and create a flat and uniform surface. Additionally, an etch cleaning process (acid etch cleaning or caustic etch cleaning) may be performed using an acid solution or a basic solution to remove damage and contaminants on the wafer surface. Afterwards, an additional step of inspecting for defects and contaminants may be performed.

In the heat treatment step S120, the wafer may be heated in a chamber containing an ambient inert gas, such as nitrogen (N2) or argon (Ar), at a temperature in a range of 500 to 1000 degrees Celsius. The purpose of this thermal process is to remove residual impurities, stabilize the wafer surface, and enhance the crystalline structure through annealing.

In the back flattening step S130, one side of the wafer can be ground again to make it flat.

In the impurity adsorption layer deposition step S140, the impurity adsorption layer 20 is deposited on the substrate 10 through LPCVD (Low-Pressure Chemical Vapor Deposition) or PECVD (Plasma-Enhanced Chemical Vapor Deposition). In the case of the PECVD method, the process is performed on an individual wafer basis, and the impurity adsorption layer 20 is deposited only on the second surface (e.g., the back surface) opposite the first surface on which the epitaxial layer 30 of the substrate 10 is to be formed. In the case of the LPCVD method, batch deposition is performed on multiple wafers simultaneously, so that an impurity adsorption layer is deposited on both the first surface and the second surface of the substrate 10. Therefore, a subsequent step is required to remove the impurity adsorption layer 20 from the first surface of the substrate 10.

In the front surface polishing step S150, one side on which the impurity adsorption layer 20 is not deposited can be grinded to make it flat. In the case of a wafer previously processed by PECVD, the flattening operation can be performed on one side on which the impurity adsorption layer 20 is not deposited. On the other hand, in the case of a wafer processed by LPCVD, the flattening operation is performed after additionally removing the impurity adsorption layer 20 deposited on the side on which the epitaxial layer is to be formed. After this, in the wafer edge grinding S160 step, the edge portion of the substrate 10 and the impurity adsorption layer 20 can be grinded again to form a shape of the substrate 10 suitable for element formation.

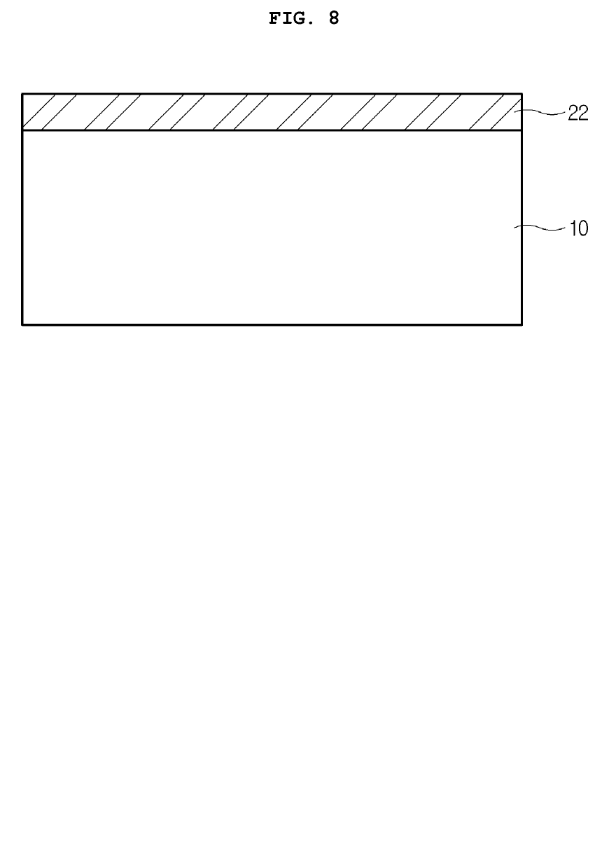

FIGS. 8 to 11 illustrate a process of depositing the impurity adsorption layer according to an embodiment. They are drawings showing a case where an impurity adsorption layer is deposited using the LPCVD method.

According to one embodiment of the present invention, in the impurity adsorption layer deposition step S140, the impurity adsorption layer 20 can be deposited on the substrate 10 through the process described later in FIGS. 8 to 11.

Referring to FIG. 8, a cleaning process can be performed before depositing a silicon oxide film 22 using TEOS (Tetra Ethyl Ortho Silicate, Si(OC2H5)4) as a precursor on the substrate 10. After cleaning using a hydrogen fluoride solution, the silicon oxide film 22 can be deposited. The silicon oxide film can be formed to a thickness of 2 nm to 500 nm.

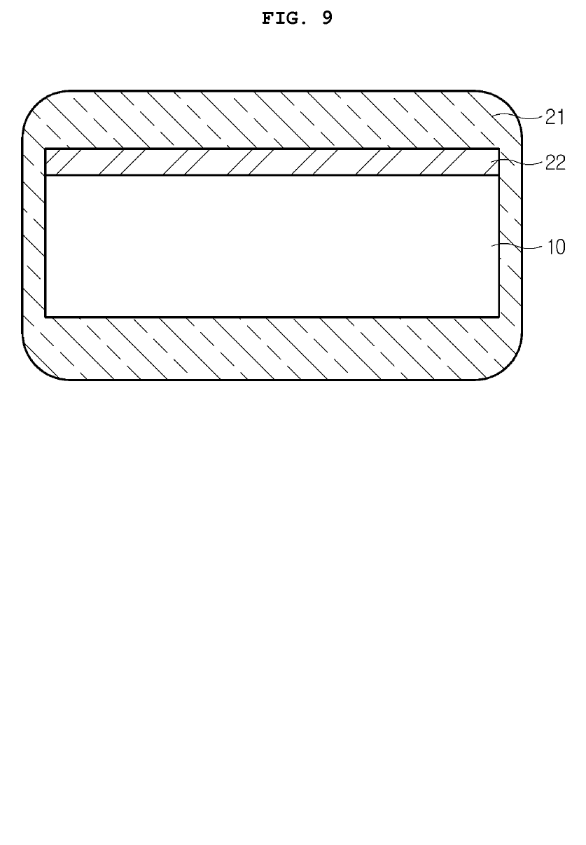

Referring to FIG. 9, the silicon oxide film 22 can be cleaned before forming the polycrystalline silicon layer 21. After the cleaning, the polycrystalline silicon layer 21 can be deposited on the upper, lower, and side surfaces of the substrate 10 and the silicon oxide film 22. The polycrystalline silicon layer 21 can be formed to a thickness of 50 nm to 5000 nm.

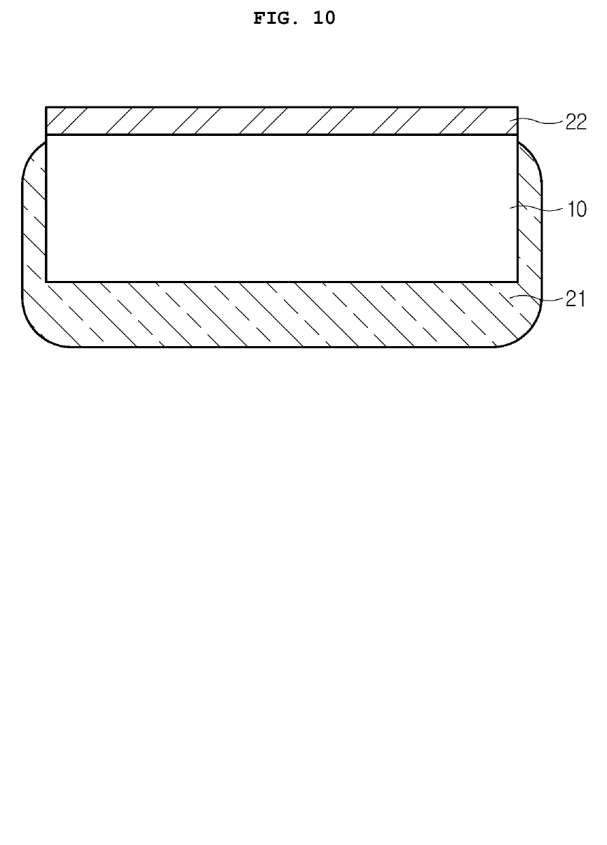

Referring to FIG. 10, the polycrystalline silicon layer 21 can be etched so that the silicon oxide film 22 is completely exposed. At this time, the surface of the substrate 10 on which the silicon oxide film 22 is not formed can be etched so that it is covered by the polycrystalline silicon layer 21.

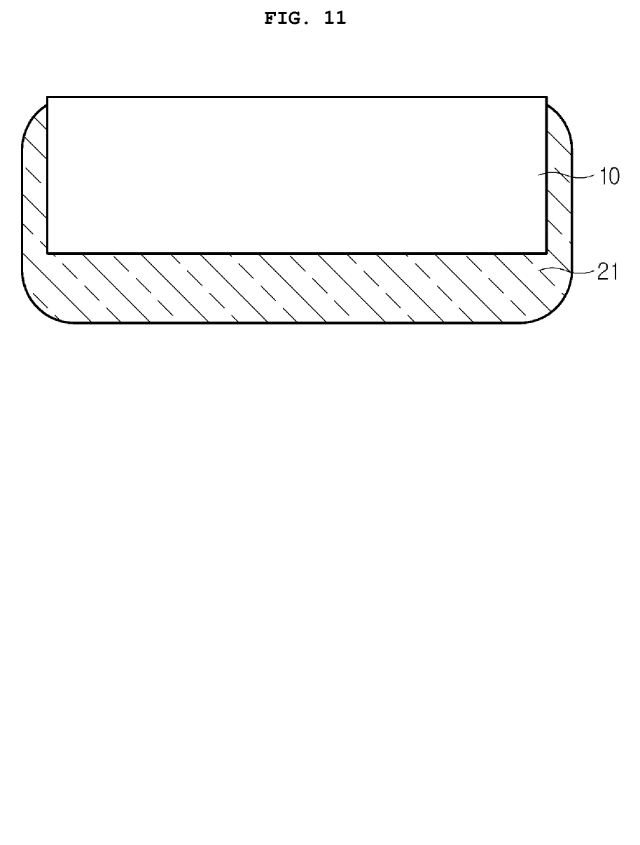

Referring to FIG. 11, the silicon oxide film 22 removal process can be performed using a hydrogen fluoride solution or a BOE (Buffered Oxide Etchant) solution. At this time, the process can be performed by setting an appropriate time under conditions that allow sufficient removal depending on the thickness of the silicon oxide film 22. According to one embodiment, the silicon oxide film 22 removal process can be performed at once by performing cleaning using sulfuric acid, BOE, and an alkaline solution.

The difficulty of the deposition process can be reduced while minimizing damage to the substrate through the method of manufacturing the substrate 10 on which the impurity adsorption layer 20 is deposited as described through FIGS. 8 to 11.

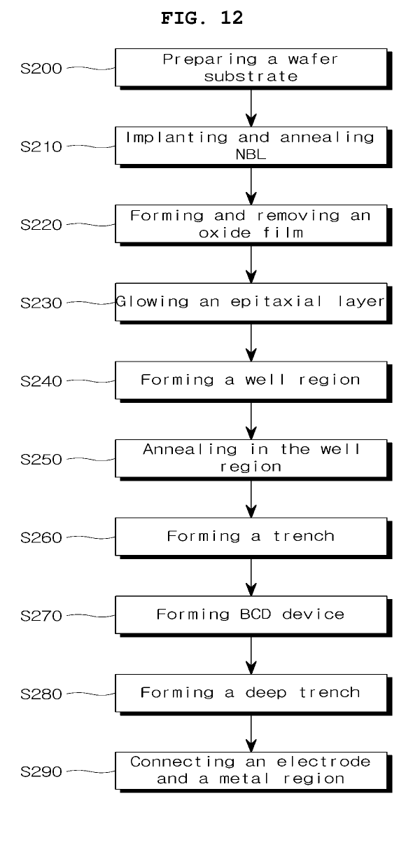

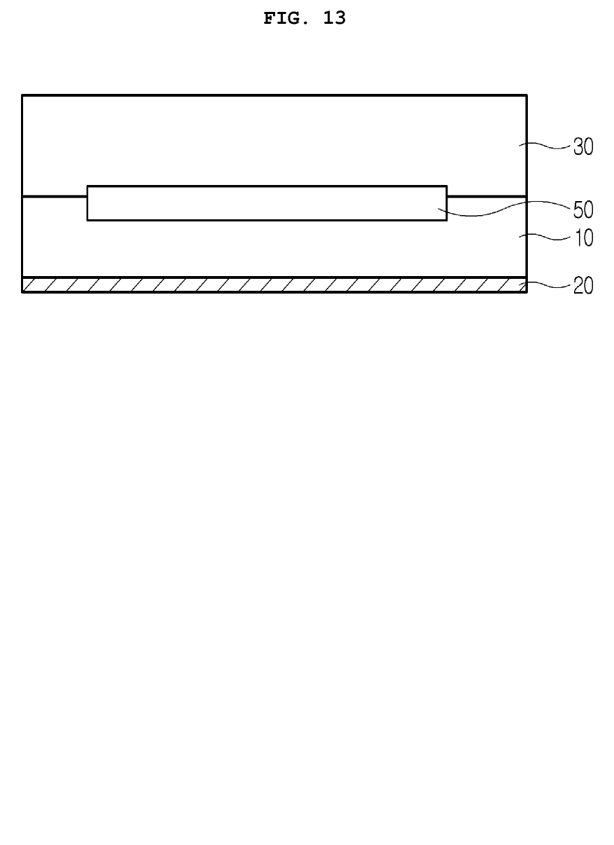

FIG. 12 illustrates a manufacturing process of a BCD semiconductor device including an impurity adsorption layer. FIGS. 13 to 16 are views showing a manufacturing method of a BCD semiconductor device including an impurity adsorption layer according to an embodiment. Referring to FIGS. 12 and 13, in the wafer substrate preparation step S200, the impurity adsorption layer 20 is deposited on the back surface of the substrate 10. The deposition method may correspond to the method described in the embodiment of the impurity adsorption layer deposition S140 described above. At this time, the wafer substrate may use an N-type doped substrate in addition to a P-type doped substrate.

In the NBL implantation and annealing step S210, the N-type buried layer (NBL) 50 is formed. The N-type buried layer 50 can be formed by implanting an N-type doping material such as arsenic (As), phosphorus (P), or antimony (Sb) into the P-type doped substrate 10 through a diffusion or ion implantation process, and then performing a heat treatment (annealing) process. In the process of injecting an N-type dopant and performing a subsequent heat treatment process, various types of micro-damages may occur on the substrate 10. Defects may occur due to such micro-damages.

According to one embodiment, in order to form the N-type buried layer 50, antimony may be doped at a concentration in a range of 1.0E14/cm² to 1.0E17/cm², and a heat treatment process may be performed at 900 to 1,300 degrees Celsius. Antimony has a larger evaporation energy than arsenic or phosphorus, so it is advantageous in that it causes less auto-doping in the subsequent epitaxial layer growth process. However, due to its relatively large atomic radius and mass, antimony can induce significant lattice strain and defects within the silicon substrate. Therefore, it is preferable to perform an extensive heat treatment during the NBL annealing step and subsequently form a thick oxide film to remove surface-level defects.

In the oxide film formation and removal step S220, an oxide film is grown to a thickness sufficient to remove implant defects (e.g., crystalline damage) that may occur after forming the N-type buried layer 50. According to one embodiment, the thickness of the oxide film may be in a range of 10 nm to 1000 nm, selected based on the severity of the lattice defect. During this process, the oxide film consumes a portion of the damaged silicon substrate surface; subsequently, after the defect is alleviated, the remaining oxide film is removed via an etching process to reveal a pristine crystal surface.

In the epitaxial layer growth step S230, the epitaxial layer 30 is formed on the substrate 10 using a crystalline material such as silicon (Si), gallium nitride (GaN), silicon carbide (SiC), or gallium arsenide (GaAs), and the crystal structure can be grown using a method such as chemical vapor deposition (CVD). The structure of the device formed up to the stage where the residual oxide film is removed and the epitaxial layer 30 is grown is illustrated in FIG. 13.

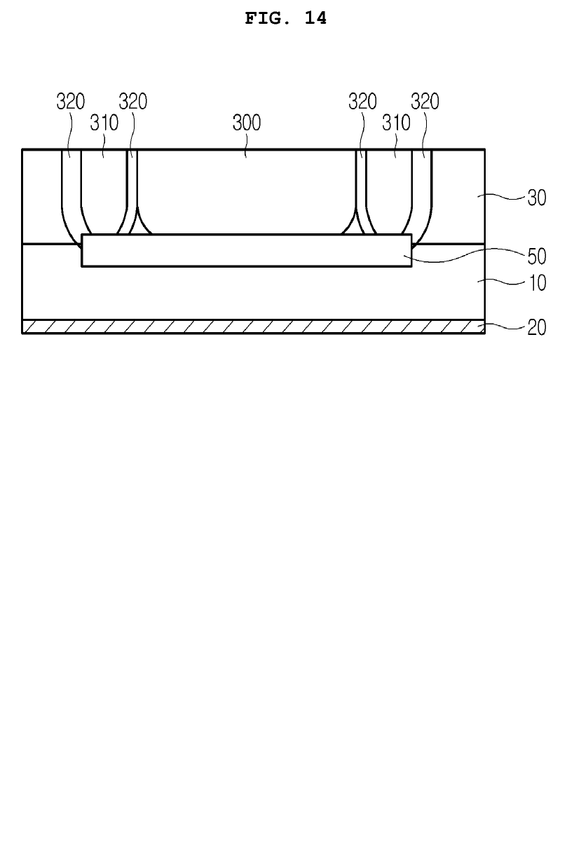

Referring to FIG. 12 and FIG. 14, in the well region formation step S240, high-voltage well regions configured for high-voltage operation and high-voltage handling are formed. As the high-voltage well region, a P-type deep well region 300, an N-type sink region 310, and a high-voltage N-type deep well region 320 can be formed. The P-type deep well region 300, the N-type sink region 310, and the high-voltage N-type deep well region 320 can be formed on top of the N-type buried layer. Based on the device characteristics to be implemented, the P-type deep well region 300, the N-type sink region 310, and the high-voltage N-type deep well region 320 may all be formed, or one or more of these high-voltage well regions may be formed to implement a desired device.

In the well region annealing step S250, a heat treatment process of 900 to 1,300 degrees Celsius may be performed on the formed high-voltage well region to allow diffusion. In the high-temperature heat treatment process, defects existing on the wafer surface and contaminants that may exist around the defects may be combined to generate unwanted compounds 65 that cause cone defects 80. However, due to the impurity adsorption layer 20 on the back surface of the wafer presented in one embodiment, all contaminants around the defect move to the impurity adsorption layer 20 on the back surface of the wafer, so that such undesired compounds 65 are not formed. The structure of a device in which a high voltage well region is formed and a heat treatment process is performed is illustrated in FIG. 14.

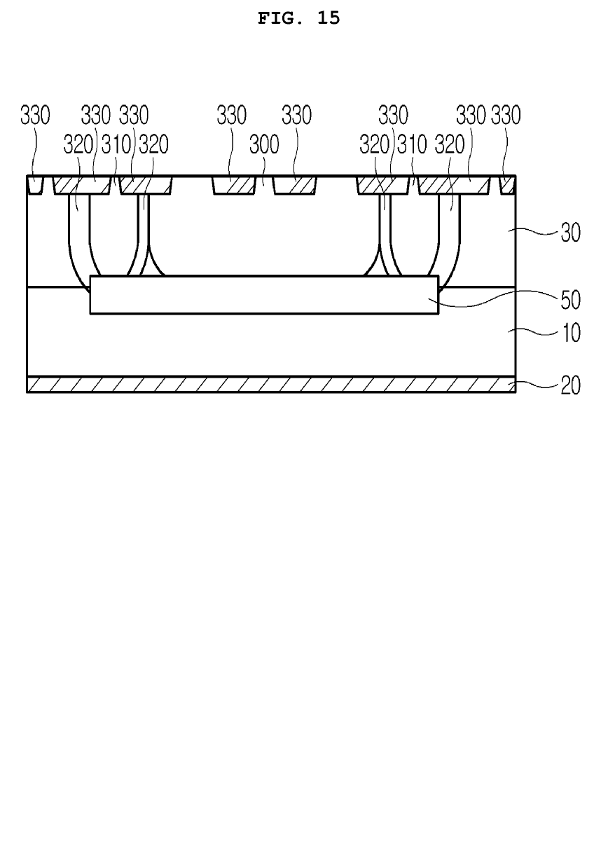

Referring to FIG. 12 and FIG. 15, in the element separation film formation step S260, an element separation film 330 is formed at an upper portion of the element through an STI (Shallow Trench Isolation) or LOCOS (Local Oxidation of Silicon) process. The element separation film 330 can be effective in insulating between elements and can increase the integration level of the element. The cone defect 80 that may occur during the formation of the element isolation film 330 can suppress the formation of the unwanted compound 65 that may act as a barrier when forming a trench on the wafer surface due to the gathering action of the impurity adsorption layer 20. The structure of the element on which the element isolation film 330 is formed is illustrated in FIG. 15.

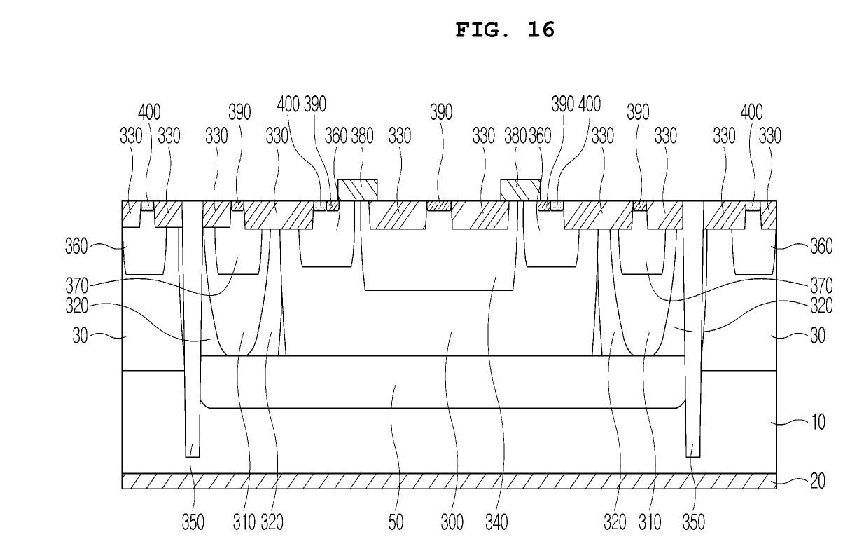

Referring to FIG. 12 and FIG. 16, in the BCD element forming step S270, an additional N-type well region 370 is formed within the N-type sink region 310, and the P-type deep well region 300 may be formed on top of the epitaxial layer 30. In addition, an N-type drift region 340 and a P-type body region 360 may be formed on top of the P-type deep well region 300, thereby enabling operation as a BCD element. In this embodiment, the N-type drift region 340 may be formed to a greater depth than the P-type body region 360. Furthermore, the N-type well region 370 may be formed with a higher dopant concentration and a shallower depth than the N-type sink region 310. A gate region 380 configured for device operation, as well as N+ regions 390 and P+ regions 400 for source/drain regions may be formed. The gate region 380 may be formed across the device isolation film 330 on the high voltage well. An N+ region 390 for drain operation may be formed in the N-type drift region 340, and an N+ region 390 and a P+ region 400 may be formed in the P-type body region 360 for the source region. In addition, an N+ region 390 may be formed on the N-type well region 370, and a P+ region 400 may be formed within the P-type body region 360.

In the deep trench formation step S280, a deep trench 350 made of an insulating material that connects from the upper surface of the device to the inside of the substrate 10 is formed, thereby effectively performing insulation between different areas inside the device. The deep trench 350 may be formed to a depth greater than the depth of the N-type buried layer 50. Furthermore, a heat treatment process may be performed during the deep trench 350 formation process, and at this time, the formation of a cone defect 80 may be suppressed by the action of an impurity adsorption layer 20. The deep trench 350 is for insulation between different areas within the device and can be selectively formed as needed. That is, the present invention contemplates a device with the deep trench (350) formed, or alternatively, a device without the deep trench 350.

In the subsequent electrode and metal region connection S290 step, metal regions such as source, drain, and gate electrodes can be connected.

The structure of a BCD element that has gone through all the steps described above is illustrated in FIG. 16.

Finally, the impurity adsorption layer 20 can be removed through the wafer back grinding process.

Although many heat treatment processes are involved in the above-described BCD semiconductor device manufacturing process, the performance of the device can be stably maintained through the process because the cone defect 80 is not formed due to the action of the impurity adsorption layer 20.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
a substrate having a first surface and a second surface opposite the first surface; and
an impurity adsorption layer comprising polycrystalline silicon disposed on the second surface of the substrate, the impurity adsorption layer configured to trap impurities introduced during a fabrication process of the semiconductor device.

2. The semiconductor device of claim 1, wherein the substrate comprises silicon, silicon carbide, or sapphire, and
wherein the substrate is doped with a P-type or an N-type dopant.

3. The semiconductor device of claim 1, wherein the impurity adsorption layer is further disposed on a lateral surface of the substrate.

4. The semiconductor device of claim 1, wherein the impurity adsorption layer has a thickness in a range of 0.05 μm to 5 μm.

5. A method of manufacturing a semiconductor device, comprising:
forming a semiconductor ingot;
grinding a surface of the semiconductor ingot to form a substrate in a shape of a wafer;
cleaning the substrate to remove foreign substances and inspecting the substrate for remaining foreign substances;
performing a heat treatment on the substrate to remove impurities from within the substrate and to flatten a first surface of the substrate;
depositing an impurity adsorption layer on a second surface of the substrate, the second surface being opposite the first surface;
polishing the first surface of the substrate; and
grinding an edge portion of the substrate and a lateral surface of the impurity adsorption layer.

6. The method of claim 5, wherein depositing the impurity adsorption layer comprises depositing polycrystalline silicon on the second surface of the substrate via a Low-Pressure Chemical Vapor Deposition (LPCVD) process or a Plasma-Enhanced Chemical Vapor Deposition (PECVD process.

7. The method of claim 5, wherein depositing the impurity adsorption layer on the second surface of the substrate comprises:
cleaning the second surface of the substrate to remove impurities;
depositing a silicon oxide film on the first surface of the substrate using tetraethyl orthosilicate (TEOS) as a precursor;
cleaning the silicon oxide film and the second surface of the substrate;
depositing a polycrystalline silicon layer on the first, second, and lateral surfaces of the substrate, such that the polycrystalline silicon layer covers the silicon oxide film;
removing a portion of the polycrystalline silicon layer covering the silicon oxide film; and
removing the silicon oxide film from the first surface of the substrate.

8. The method of claim 7, wherein depositing the silicon oxide film on the first surface of the substrate comprises depositing the silicon oxide film to a thickness in a range of 2 nm to 500 nm.

9. The method of claim 7, wherein depositing the polycrystalline silicon layer on the first, second, and lateral surfaces of the substrate and the silicon oxide film comprises depositing the polycrystalline silicon layer to a thickness in a range of 50 nm to 5000 nm.

10. A semiconductor device comprising:
a substrate comprising silicon, silicon carbide, or sapphire, the substrate being doped with a P-type dopant and having a first surface and a second surface opposite the first surface;
an impurity adsorption layer comprising polycrystalline silicon disposed on the second surface of the substrate;
an N-type buried layer disposed on the first surface of the substrate;
an epitaxial layer disposed on the N-type buried layer;
a high voltage N-type deep well region and a P-type deep well region disposed in the epitaxial layer;
a device isolation film comprising an insulating material disposed on an upper portion of the epitaxial layer;
a P-type well region disposed in the epitaxial layer or the P-type deep well region;
an N-type well region disposed in the high voltage N-type deep well region; and
a drain electrode, a source electrode, and a gate electrode disposed on the epitaxial layer.

11. The semiconductor device of claim 10, further comprising:
an N-type sink region disposed within the high voltage N-type deep well region; and
a deep trench comprising an insulating material, the deep trench extending from an upper portion of the epitaxial layer, through the N-type buried layer, and into the substrate.

12. A method of manufacturing a semiconductor device, comprising:
providing a substrate comprising silicon, silicon carbide, or sapphire, the substrate being doped with a P-type dopant and having a first surface and a second surface opposite the first surface;
forming an impurity adsorption layer by depositing polycrystalline silicon on the second surface of the substrate;
forming an N-type buried layer on the first surface of the surface;
forming an epitaxial layer on the N-type buried layer;
forming a high voltage N-type deep well region and a P-type deep well region in the epitaxial layer;
forming a device isolation film comprising an insulating material on an upper portion of the epitaxial layer;
forming a P-type well region within at least one of the epitaxial layer and the P-type deep well region;
forming an N-type well region within the high voltage N-type deep well region;
forming a gate electrode on the epitaxial layer; and
forming an N+ region and a P+ region within the N-type well region and the P-type well region, respectively, to define source and drain regions.

13. The method of claim 12, wherein forming the N-type buried layer on the first surface of the substrate comprises:
doping the first surface of the substrate with antimony (Sb) at a concentration in a range of 1.0E14/cm² to 1.0E17/cm²; and
performing a heat treatment process at a temperature in a range of 900 °C to 1,300 °C to diffuse the antimony and form the N-type buried layer.

14. The method of claim 12, further comprising:
forming a plurality of N-type sink regions within the high voltage N-type deep well region prior to forming the device isolation film; and
performing a heat treatment process at a temperature in a range of 900 °C to 1,300 °C to drive in the N-type sink region.

15. The method of claim 12, further comprising:
forming a deep trench comprising an insulating material, the deep trench extending from an upper surface of the epitaxial layer, through the N-type buried layer, and into the substrate,
wherein forming the deep trench is performed after forming the gate electrode.

16. The method of claim 12, further comprising:
performing a heat treatment process at a temperature in a range of 900 °C to 1,300 °C during the forming of the P-type deep well region and the high voltage N-type deep well region.

17. The method of claim 12, wherein forming the device isolation film on the upper portion of the epitaxial layer further comprises,
performing a heat treatment process at a temperature in a range of 900 °C to 1,300 °C.

18. The method of claim 15, further comprising:
performing a heat treatment process at a temperature in a range of 900 °C to 1,300 °C during the forming of the deep trench.

19. The method of claim 12, further comprising:
forming an N-type drift region and a P-type body region within an upper portion of the P-type deep well region, subsequent to forming the high voltage N-type deep well region and the P-type deep well region.

20. The method of claim 19, wherein forming the N+ region and the P+ region comprises:
forming an N+ drain region within the N-type drift region; and
forming an N+ source region and a P+ region within the P-type body region.
